(19) United States
(12) Patent Application Publication
(10) Pub. No.: US 2011/0248259 A1
(43) Pub. Date: Oct. 13, 2011

(54) Organic light emitting device and method of manufacturing the same

(76) Inventors: Il-Soo Oh, Yongin-City (KR); Chang-Ho Lee, Yongin-City (KR); Hee-Joo Ko, Yongin-City (KR); Se-Jin Cho, Yongin-City (KR); Hyung-Jun Song, Yongin-City (KR); Jin Young Yun, Yongin-City (KR); Jong-Hyuk Lee, Yongin-City (KR)

(21) Appl. No.: 13/064,670

(22) Filed: Apr. 7, 2011

(30) Foreign Application Priority Data
Apr. 8, 2010 (KR) 10-2010-0032286

(51) Int. Cl. H01L 51/50; H01L 51/40

(52) U.S. Cl. 257/43; 438/23; 257/E51.018; 257/E33.053; 257/E51.001

(57) ABSTRACT

An organic light emitting device and a method of manufacturing the same, the device including a substrate; a thin film transistor on the substrate, the thin film transistor including source and drain electrodes, an oxide semiconductor layer, a gate electrode, and a gate insulating layer that insulates the gate electrode from the source and drain electrodes; a first insulating layer on the thin film transistor; a cathode on the first insulating layer, the cathode being connected to one of the source and drain electrodes of the thin film transistor; a first layer on the cathode, the first layer including a first material, the first material including at least one of metal, metal sulfide, metal oxide, and metal nitride; an organic layer on the first layer; and an anode on the organic layer.

### BACKGROUND

1. Field

Embodiments relate to an organic light emitting device and a method of manufacturing the same.

2. Description of the Related Art

Organic light emitting devices (OLEDs), which are self-emitting devices, have advantages such as a wide viewing angle, excellent contrast, quick response, high brightness, excellent driving voltage characteristics, and can provide multicolored images.

A conventional OLED includes an anode, a cathode, and an organic layer interposed between the anode and the cathode. The organic layer may include a hole transport layer (HTL), an emission layer (EML), an electron transport layer (ETL), and a cathode. The OLED may also include a driving transistor or a switching transistor.

An operating principle of an OLED having the above-described structure is as follows.

When a voltage is applied between the anode and the cathode, holes injected from the anode may move to the EML via the HTL; and electrons injected from the cathode may move to the EML via the ETL. The holes and electrons may recombine in the EML to generate excitons. When the excitons drop from an excited state to a ground state, light is emitted.

Research is being conducted to prepare an organic layer using a wet process in order to manufacture a large-sized OLED.

### SUMMARY

Embodiments are directed to an organic light emitting device and a method of manufacturing the same, which represent advances over the related art.

At least one of the above and other features and advantages may be realized by providing an organic light emitting device including a substrate; a thin film transistor on the substrate, the thin film transistor including source and drain electrodes, an oxide semiconductor layer, a gate electrode, and a gate insulating layer that insulates the gate electrode from the source and drain electrodes; a first insulating layer on the thin film transistor; a cathode on the first insulating layer, the cathode being connected to one of the source and drain electrodes of the thin film transistor; a first layer on the cathode, the first layer including a first material, the first material including at least one of metal, metal sulfide, metal oxide, and metal nitride; an organic layer on the first layer; and an anode on the organic layer.

The oxide semiconductor layer may include a zinc-containing oxide.

The oxide semiconductor layer may further include a first component, the first component including at least one of hafnium (Hf), yttrium (Y), tantalum (Ta), zirconium (Zr), gallium (Ga), aluminum (Al), indium (In), iron (Fe), scandium (Sc), lutetium (Lu), ytterbium (Yb), thulium (Tm), erbium (Er), holmium (Ho), manganese (Mn), cobalt (Co), nickel (Ni), titanium (Ti), germanium (Ge), copper (Cu), molybdenum (Mo), and tin (Sn).

The cathode may include a material including at least one of magnesium (Mg), aluminum (Al), calcium (Ca), indium (In), and silver (Ag).

The first material of the first layer may have a work function of about 2.6 eV to about 4.6 eV.

The first material of the first layer may include at least one of potassium (K), rubidium (Rb), cesium (Cs), magnesium (Mg), strontium (Sr), barium (Ba), scandium (Sc), yttrium (Y), titanium (Ti), manganese (Mn), zinc (Zn), ytterbium (Yb), potassium sulfide, rubidium sulfide, cesium sulfide, magnesium sulfide, strontium sulfide, barium sulfide, scandium sulfide, yttrium sulfide, titanium sulfide, manganese sulfide, zinc sulfide, ytterbium sulfide, potassium oxide, rubidium oxide, cesium oxide, magnesium oxide, strontium oxide, barium oxide, scandium oxide, yttrium oxide, titanium oxide, manganese oxide, zinc oxide, ytterbium oxide, potassium nitride, rubidium nitride, cesium nitride, magnesium nitride, strontium nitride, barium nitride, scandium nitride, yttrium nitride, titanium nitride, manganese nitride, zinc nitride, and ytterbium nitride.

The first layer may further include an electron injecting material.

The first layer may have a thickness of about 3 nm to about 30 nm.

The organic light emitting device may further include an electron injection layer interposed between the first layer and the cathode.

At least one of the above and other features and advantages may also be realized by providing a method of manufacturing an organic light emitting device, the method including providing a substrate; forming a thin film transistor on the substrate such that the thin film transistor includes source and drain electrodes, an oxide semiconductor layer, a gate electrode, and a gate insulating layer that insulates the gate electrode from the source and drain electrodes; forming a first insulating layer on the thin film transistor; forming a cathode on the first insulating layer such that the cathode is connected to one of the source and drain electrodes of the thin film transistor; forming a first layer on the cathode by deposition or sputtering such that the first layer includes a first material including at least one of metal, metal sulfide, metal oxide, and metal nitride; forming an organic layer on the first layer; and forming an anode on the organic layer.

The oxide semiconductor layer may further include a first component, wherein the first component includes at least one of hafnium (Hf), yttrium (Y), tantalum (Ta), zirconium (Zr), gallium (Ga), aluminum (Al), indium (In), iron (Fe), scandium (Sc), lutetium (Lu), ytterbium (Yb), thulium (Tm), erbium (Er), holmium (Ho), manganese (Mn), cobalt (Co), nickel (Ni), titanium (Ti), germanium (Ge), copper (Cu), and molybdenum (Mo).

The first material of the first layer may have a work function of about 2.6 eV to about 4.6 eV.

The first material of the first layer may include at least one of potassium (K), rubidium (Rb), cesium (Cs), magnesium (Mg), strontium (Sr), barium (Ba), scandium (Sc), yttrium (Y), titanium (Ti), manganese (Mn), zinc (Zn), ytterbium (Yb), potassium sulfide, rubidium sulfide, cesium sulfide, magnesium sulfide, strontium sulfide, barium sulfide, scandium sulfide, yttrium sulfide, titanium sulfide, manganese sulfide, zinc sulfide, ytterbium sulfide, potassium oxide, rubidium oxide, cesium oxide, magnesium oxide, strontium oxide, barium oxide, scandium oxide, yttrium oxide, titanium oxide, manganese oxide, zinc oxide, ytterbium oxide, potassium nitride, rubidium nitride, cesium nitride, magnesium nitride, strontium nitride, barium nitride, scandium nitride, yttrium nitride, titanium nitride, manganese nitride, zinc nitride, and ytterbium nitride.

Forming the first layer may include depositing or sputtering a first material-forming material and an electron injecting material.

The method may further include forming an electron injection layer on the cathode prior to forming the first layer.

Forming the organic layer may include spin coating, spraying, inkjet printing, dipping, casting, gravure coating, bar coating, roll coating, wire-bar coating, screen coating, flexo coating, or offset coating.

Forming the organic layer may include providing a mixture including a light emitting material and a solvent onto a region on which an emission layer is formed (for example, on the first layer, an electron transport layer or a hole blocking layer), and heating the substrate including the mixture thereon. Forming the organic layer may include providing a mixture including a hole injecting material and a solvent onto a region on which a hole injection layer is formed (for example, on the emission layer or a hole transport layer), and heating the substrate including the mixture thereon.

Forming the organic layer may include providing a mixture including a hole transporting material and a solvent onto a region on which a hole transport layer is formed (for example, on transport layer), and heating the substrate including the mixture thereon.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic sectional view of a structure of an organic light emitting device according to an embodiment;

FIG. 2 illustrates a schematic sectional view of a structure of an organic light emitting device according to another embodiment;

FIG. 3 illustrates a graph showing voltage-current density characteristics of Device 1 measured twice; and

FIG. 4 illustrates a graph showing voltage-brightness characteristics of Device 1 and Device 2.

### DETAILED DESCRIPTION

Korean Patent Application No. 10-2010-0032286, filed on Apr. 8, 2010, in the Korean Intellectual Property Office, and entitled: “Organic Light Emitting Device and Method of Manufacturing the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

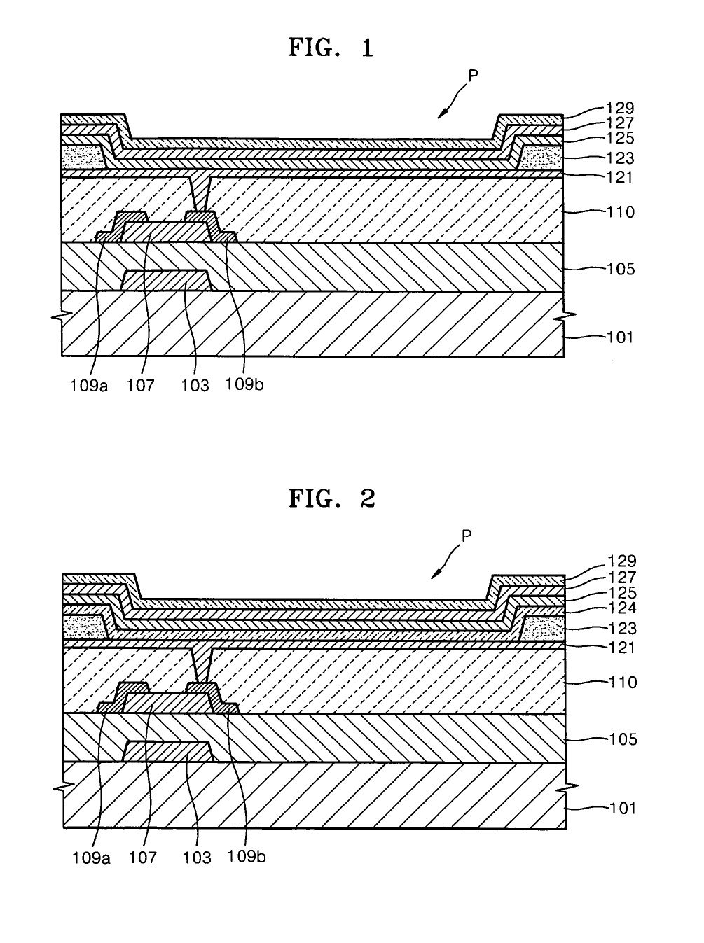

FIG. 1 illustrates a schematic sectional view showing a structure of an organic light emitting device (OLED) according to an embodiment.

The OLED may include a thin film transistor that is formed on a substrate 101. The thin film transistor may include a source electrode 109a, a drain electrode 109b, an oxide semiconductor layer 107, a gate electrode 103, and a gate insulating layer 105 that insulates the gate electrode 103 from the source electrode 109a and the drain electrode 109b. A first insulating layer 110 may be formed on the thin film transistor. In addition, a cathode 121 may be formed on the first insulating layer 110 and may be connected to one of the source electrode 109a or the drain electrode 109b of the thin film transistor. A pixel region may be defined by a pixel defining layer 123. A first layer 125, an organic layer 127, and an anode 129 may be sequentially stacked on the cathode 121.

The substrate 101, which may be any suitable substrate that is used in organic light emitting devices, may be, e.g., a glass substrate or a transparent plastic substrate with excellent mechanical strength, thermal stability, transparency, surface smoothness, ease of handling, and water resistance.

The gate electrode 103 may include any suitable material commonly used to for an electrode, e.g., metal. For example, the gate electrode 103 may include aluminum (Al), hafnium (Hf), zirconium (Zr), zinc (Zn), tungsten (W), cobalt (Co), gold (Au), platinum (Pt), ruthenium (Ru), iridium (Ir), titanium (Ti), tantalum (Ta), nickel (Ni), silver (Ag), molybdenum (Mo), copper (Cu), palladium (Pd), indium (In), tin (Sn), a combination of at least two thereof (alloy, mixture, etc.), an oxide including at least one of the material listed above (e.g., indium tin oxide (ITO), indium zinc oxide (lZO), etc.), but is not limited thereto.

The gate insulating layer 105 may cover the gate electrode 103 to insulate the gate electrode 103 from the source electrode 109a and the drain electrode 109b. The gate insulating layer 105 may include, e.g., a silicon oxide layer or a silicon nitride layer. However, the gate insulating layer 105 may also be a layer formed of any other material, e.g., a high dielectric material layer that has higher dielectric constant than the silicon nitride. The gate insulating layer 105 may have a stacked structure including at least two of a silicon oxide layer, a silicon nitride layer, and a high dielectric material layer.

In the oxide semiconductor layer 107, an oxide semiconductor may have a band gap that is greater than photoenergy of visible rays so as not to substantially absorb visible rays. Accordingly, undesirable current leak caused by the absorption of visible rays may not substantially increase in the thin film transistor including the oxide semiconductor layer 107.

The oxide semiconductor layer 107 may include a zinc-containing oxide. For example, the oxide semiconductor layer 107 may include ZnO.

The zinc-containing oxide may further include a first component including, e.g., hafnium (Hf), yttrium (Y), tantalum (Ta), zirconium (Zr), gallium (Ga), aluminum (Al), indium (In), iron (Fe), scandium (Sc), lutetium (Lu), ytterbium (Yb), thulium (Tm), erbium (Er), holmium (Ho), manganese (Mn), cobalt (Co), nickel (Ni), titanium (Ti), germanium (Ge), copper (Cu), molybdenum (Mo), tin (Sn), and/or a combination of at least two thereof.

For example, the oxide semiconductor layer 107 may include a Zn—Ga—O-based material, a Zn—In—O-based material, a Zn—In—Ga—O-based material, a Zn—Sn—O-based material, or a Hf—In—Zn—O-based material, but is not limited thereto.

The source electrode 109a and the drain electrode 109b that are in contact with ends of the oxide semiconductor layer 107 may be formed on the gate insulating layer 105. The source electrode 109a and the drain electrode 109b may be, e.g., a single-layered metal layer or a multi-layered metal layer. Materials used to form the source electrode 109a and the drain electrode 109b may be defined as describe above with reference to materials used to form the gate electrode 103.

The thin film transistor may be prepared using any suitable method known in the art.

The first insulating layer 110 of FIG. 1 may be formed so as to cover the thin film transistor as described above. The first insulating layer 110 may function as a protective layer and/or planarization layer. The first insulating layer 110 may be, e.g., a silicon oxide layer or a silicon nitride layer. However, the first insulating layer 110 may also be a layer formed of any other suitable material, e.g., a high dielectric material layer that has higher dielectric constant than the silicon nitride. The first insulating layer 110 may have a stacked structure including at least two of a silicon oxide layer, a silicon nitride layer, and a high dielectric material layer. The first insulating layer 110 may be formed using various methods, e.g., coating, deposition, and sputtering.

The cathode 121 may be formed on the first insulating layer 110. The cathode 121 may be electrically connected to the drain electrode 109b through a via hole. The cathode 121 may be an electrode injecting electrons to the organic layer 127 via the first layer 125.

The cathode 121 may include an alkali metal, e.g., lithium (Li), sodium (Na), potassium (K), rubidium (Rb), or cesium (Cs); an alkali earth metal, e.g., beryllium (Be), magnesium (Mg), calcium (Ca), strontium (Sr), or barium (Ba); a metal, e.g., aluminum (Al), scandium (Sc), vanadium (V), zinc (Zn), yttrium (Y), indium (In), cerium (Ce), samarium (Sm), europium (Eu), terbium (Tb), or ytterbium (Yb); an alloy of at least two of these metals; an alloy of at least one of these metals with at least one of, e.g., gold (Au), silver (Ag), platinum (Pt), copper (Cu), manganese (Mn), titanium (Ti), cobalt (Co), nickel (Ni), tungsten (W), and tin (Sn); or a combination of at least two thereof. The combination may include an alloy including at least two elements described above and a multi-layered structure, each of which includes the elements described above. Examples of the alloy that may be used to form the cathode 121 may include a Mg—Ag alloy, a Mg—In alloy, a Mg—Al alloy, an In—Ag alloy, a Li—Al alloy, a Li—Mg alloy, a Li—In alloy, and a Ca—Al alloy. For example, the cathode 121 may include a material including Mg, Al, Ca, In, Ag, and a combination of at least two thereof, but is not limited thereto. Alternatively, the cathode 121 may include a metal oxide, e.g., indium tin oxide (ITO), indium zinc oxide (IZO), and zinc oxide and an oxide of at least two alloy thereof. The cathode 121 may be formed using various methods, e.g., deposition and/or sputtering.

The pixel defining layer 123 that define pixel regions may be formed at ends of the cathode 121. The pixel defining layer 123 may be formed of a suitable organic insulating material.

The first layer 125 may be formed on the cathode 121.

The first layer 125 may include a first material including, e.g., metal, metal sulfide, metal oxide, metal nitride, and/or a combination of at least two thereof.

The first material may have a work function of about 2.6 eV to about 4.6 eV, for example, about 2.6 eV to about 4.2 eV. Maintaining the work function of the first layer 125 at about 2.6 eV to about 4.6 eV may help ensure that electrons are efficiently injected from the cathode 121, so that an OLED having high efficiency and high brightness may be manufactured.

The first material may include, e.g., potassium (K), rubidium (Rb), cesium (Cs), magnesium (Mg), strontium (Sr), barium (Ba), scandium (Sc), yttrium (Y), titanium (Ti), manganese (Mn), zinc (Zn), ytterbium (Yb), potassium sulfide, rubidium sulfide, cesium sulfide, magnesium sulfide, strontium sulfide, barium sulfide, scandium sulfide, yttrium sulfide, titanium sulfide, manganese sulfide, zinc sulfide, ytterbium sulfide, potassium oxide, rubidium oxide, cesium oxide, magnesium oxide, strontium oxide, barium oxide, scandium oxide, yttrium oxide, titanium oxide, manganese oxide, zinc oxide, ytterbium oxide, potassium nitride, rubidium nitride, cesium nitride, magnesium nitride, strontium nitride, barium nitride, scandium nitride, yttrium nitride, titanium nitride, manganese nitride, zinc nitride, ytterbium nitride, and/or a combination of at least two thereof. The “combination of at least two thereof” may be a material including two or more different metals (e.g., Ba—Cs—O-based material) or a material including at least two selected from the group consisting of O, S and N (e.g., Zn—O—N-based material).

The first material may vary to control the work function of the first layer 125 as will be described below.

For example, the first material may include ZnS.

Alternatively, the first material may include, e.g., Sc₂O₃, CsO, BaO, and/or RbO.

Alternatively, the first material may include, e.g., yttrium sulfide, ytterbium sulfide, rubidium sulfide, strontium sulfide, cesium sulfide, barium sulfide, titanium sulfide, manganese sulfide, yttrium oxide, ytterbium oxide, rubidium oxide, strontium oxide, cesium oxide, barium oxide, titanium oxide, manganese oxide, yttrium nitride, ytterbium nitride, rubidium nitride, strontium nitride, cesium nitride, barium nitride, titanium nitride, and/or manganese nitride.

In an implementation, the first material may include, e.g., ZnS and Sc₂O₃ and at least one of magnesium sulfide, yttrium sulfide, ytterbium sulfide, magnesium oxide, yttrium oxide, ytterbium oxide, magnesium nitride, yttrium nitride, and ytterbium nitride.

Alternatively, the first material may include, e.g., ZnS and Sc₂O₃ and at least one of Mg, Y, and Yb.

Alternatively, the first material may include, e.g., titanium sulfide, titanium oxide, titanium nitride, manganese sulfide, manganese oxide, and manganese nitride and at least one of yttrium sulfide, ytterbium sulfide, rubidium sulfide, cesium sulfide, barium sulfide, potassium sulfide, yttrium oxide, ytterbium oxide, rubidium oxide, cesium oxide, barium oxide, potassium oxide, yttrium nitride, ytterbium nitride, rubidium nitride, cesium nitride, barium nitride, and potassium nitride, but is not limited thereto.

The first layer 125 may further include an electron injecting material in addition to the first material described above. The electron injecting material may be any suitable material that is commonly used to form an electron injection layer (EIL) of the organic light emitting device.

For example, the electron injecting material may include LiF, NaCl, CsF, Li₂O, and/or BaF₂, but is not limited to. For example, the electron injecting material may be LiF, but is not limited thereto.

For example, the first layer 125 may further include an electron injecting material in addition to the first material, wherein the first material may be ZnS, and the electron injecting material may be LiF.

If the first layer 125 further includes the electron injecting material, a weight ratio of the first material to the electron injecting material may vary according to, e.g., the type of the first material, the type of the electron injecting material, or the like, an may be about 10:1 to about 1:10, for example, about 4:1 to about 1:4.

A thickness of the first layer 125 may be about 3 nm to about 30 nm, for example, about 5 nm to about 20 nm. Maintaining the thickness of the first layer 125 at about 3 nm to about 30 nm may help ensure that the first layer 125 provides satisfactory electron injecting properties without an increase in driving voltage.

For example, the first layer 125 may be formed using deposition (e.g., thermal deposition) or sputtering.

For example, the first layer 125 may be formed by deposition (e.g. thermal depositing) or sputtering a first material-forming material.

The “first material-forming material” used herein may be the first material described above or a material including elements contained in the first material to be used as a source of deposition or sputtering. For example, if a first layer including ZnS as the first material is formed using sputtering, the first material-forming material may be a ZnS target, or Zn target and an S target, which are known in the art.

In addition, if the first layer 125 includes the electron injecting material in addition to the first material, the first layer 125 may be formed by depositing or sputtering the first material-forming material and the electron injecting material.

For example, the first layer 125 may be formed by co-depositing ZnS and LiF.

The organic layer 127 may be formed on the first layer 125. The organic layer 127 may include, e.g., a hole blocking layer (HBL), an emission layer (EML), a hole transport layer (HTL), and/or a hole injection layer (HIL) having a structure, material, and thickness that are commonly used to manufacture an OLED. The material contained in the organic layer 127 is not limited to an organic material, the organic layer 127 may also include a metal complex, e.g., an iridium complex as a light emitting dopant.

For example, the organic layer 127 may include a polymer. For example, the organic layer 127 may further include at least one layer including an electron transport layer (ETL), a HBL, an EML, a HTL, and/or a HIL, which may be sequentially stacked on the first layer 125 in this order.

The ETL may be formed using, e.g., vacuum deposition or by providing a mixture of an electron transporting material and a solvent to an ETL forming region and heating the mixture, i.e., a wet process. The mixture including the electron transporting material and the solvent may be provided to the ETL forming region using various methods, e.g., spin coating, casting, inkjet printing, and/or Langmuir Blodgett (LB).

When the ETL is formed using vacuum deposition, the deposition conditions may vary according to the material that is used to form the ETL, and the structure and thermal properties of the ETL to be formed. For example, conditions for vacuum deposition may include a deposition temperature of about 100 to about 500° C., a pressure of about 10⁻⁸ to about 10⁻³ torr, and a deposition rate of about 0.01 to about 100 Å/sec.

When the ETL is formed using spin coating, the coating conditions may vary according to the material that is used to form the ETL, and the structure and thermal properties of the ETL to be formed. For example, conditions for spin coating may include a coating rate of about 2000 to about 5000 rpm, and a heat treatment temperature of about 80 to about 300° C. for removing a solvent after coating.

Examples of the material that may be used to form the ETL may include any suitable materials, e.g., a 4,7-diphenyl-1,10-phenanthroline (Bphen), BAlq, tris(8-quinol inorate)aluminum (Alq₃), beryllium bis(benzoquinolin-10-olate (Bebq₂), or TPBi.

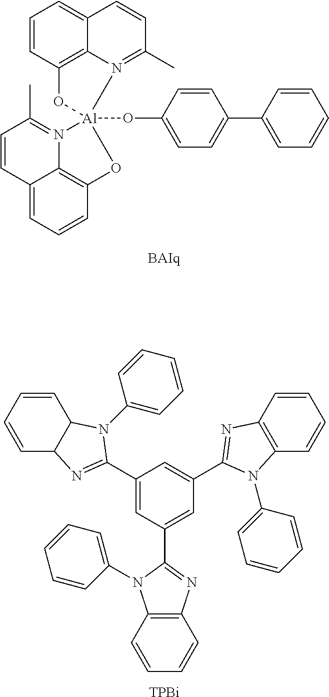

A thickness of the ETL may be about 100 to about 1000 Å, for example, about 200 to about 500 Å. Maintaining the thickness of the ETL at about 100 to about 1000 Å may help ensure that the ETL provides satisfactory electron transporting properties without a substantial increase in driving voltage.

The HBL may be formed using the method of forming the ETL as described above. Examples of the material that is used to form the HBL may include an oxadiazole derivative, a triazole derivative, a phenanthroline derivative, and TAZ, but are not limited thereto.

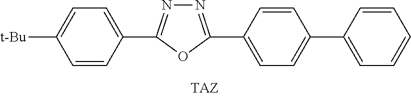

A thickness of the HBL may be about 50 to about 1000 Å, for example, about 100 to about 300 Å. Maintaining the thickness of the HBL at about 50 to about 1000 Å may help ensure that the HBL provides excellent hole blocking properties.

The EML may be formed of anylight emitting material. The light emitting material may include a combination of a host and a dopant. A region on which the EML is formed may be on the first layer (125), the ETL or the HBL. Examples of the host may include Alq₃, 4,4′-N,N′-dicarbazole-biphenyl (CBP), poly(n-vinylcarbazole) (PVK), 9,10-di(naphthalene-2-yl)anthracene (ADN), TCTA, 1,3,5-tris(N-phenylbenzimidazole-2-yl)benzene (TPBI), 3-tert-butyl-9,10-di-2-naphthylanthracene (TBADN), E3, and distyrylarylene (DSA), bur are not limited thereto.

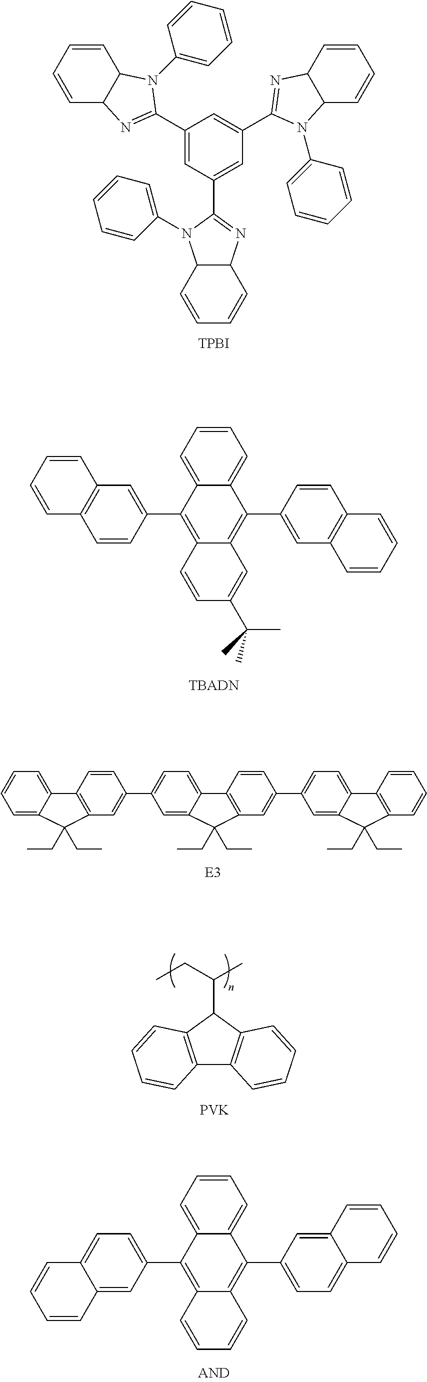

Examples of red dopants may include PtOEP, Ir(piq)3, and Btp2Ir(acac), but are not limited to.

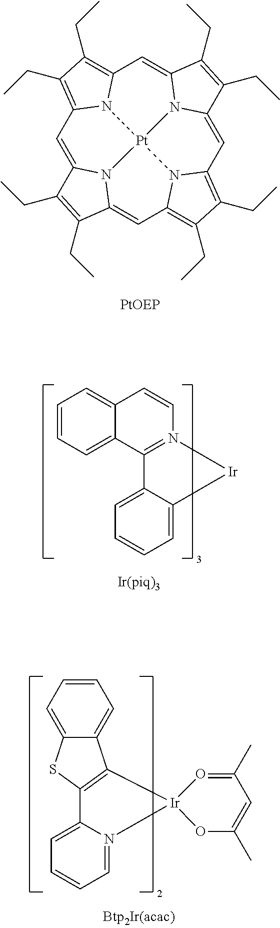

Examples of green dopants may include Ir(ppy)₃(ppy=phenylpyridine), Ir(ppy)₂(acac), and Ir(mpyp)₃, but are not limited thereto.

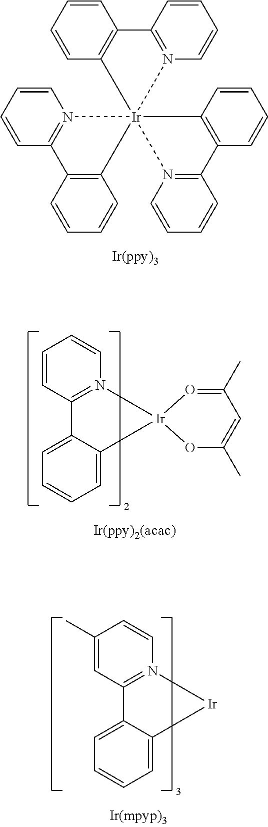

Examples of blue dopants may include F₂Irpic, (F₂ppy)₂Ir(tmd), Ir(dfppz)₃, ter-fluorene, 4,4′-bis(4-diphenylaminostyryl)biphenyl (DPAVBi), and 2,5,8,11-tetra-tert-butyl pherylene (TBPe), but are not limited thereto.

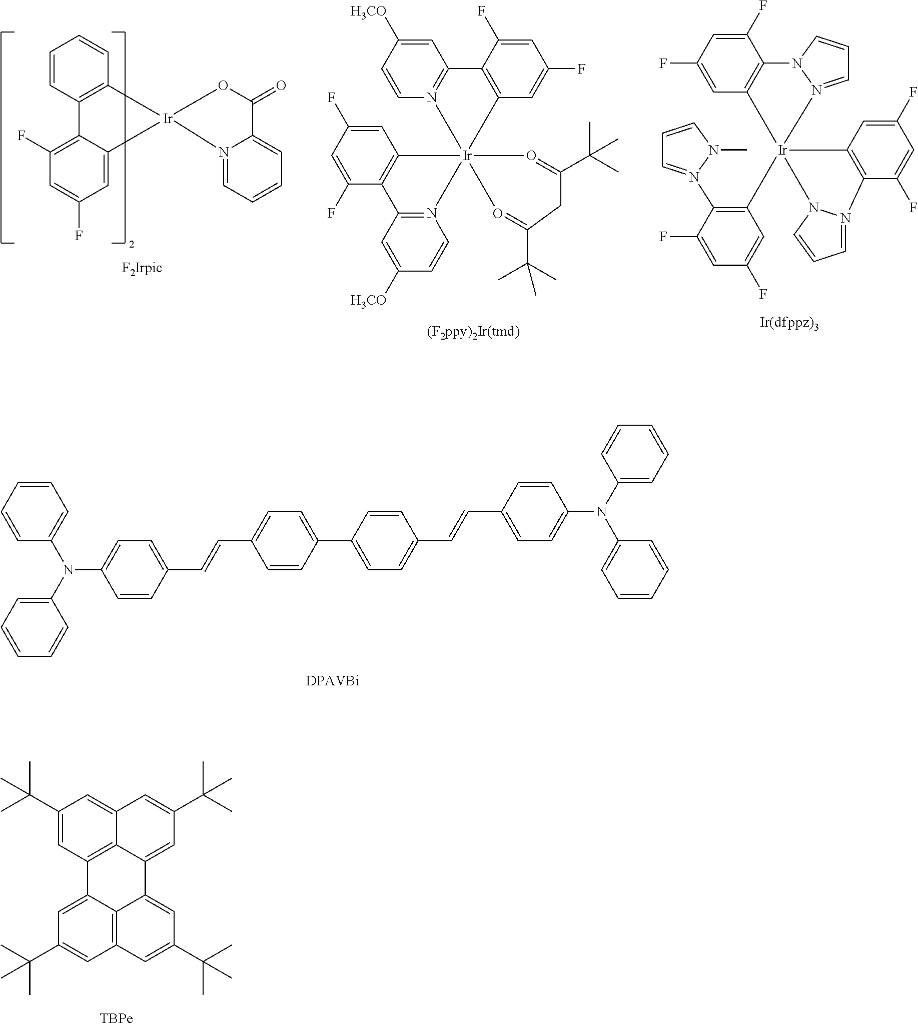

If the EML includes the host and the dopant, the amount of the dopant may be about 0.01 to about 15 parts by weight, based on 100 parts by weight of the host, but is not limited thereto.

A thickness of the EML may be about 100 Å to about 1000 Å, for example, about 200 Å to about 600 Å. Maintaining the thickness of the EML at about 100 Å to about 1000 Å may help ensure that the EML provides excellent light emitting ability without a substantial increase in driving voltage.

A material used to form the HTL may be any suitable hole transporting material. Examples of the material may include N,N′-bis(3-methylphenyl)-N,N′-diphenyl-[1,1-biphenyl]-4,4′-diamine (TPD), N,N′-di(naphthalene-1-yl)-N,N′-diphenyl benzidine (NPD), N,N′-diphenyl-N,N′-bis(1-naphthyl)-(1,1′-biphenyl)-4,4′-diamine (NPB), and the like, but are not limited to.

A thickness of the HTL may be about 50 to 1,000 Å, for example, about 100 to about 600 Å. Maintaining the thickness of the HTL at about 50 to 1,000 Å may help ensure that the HTL provides satisfactory hole transporting properties without a substantial increase in driving voltage. The HTL may have a structure including at least one layer.

A material used to form the HIL may include any suitable hole injecting material. Examples of the material may include 4,4′,4″-tris(3-methylphenylphenylamino) triphenylamine (m-MTDATA), TDATA, 2T-NATA, polyaniline/dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), and polyaniline/poly(4-styrenesulfonate) (PANI/PSS), but are not limited thereto.

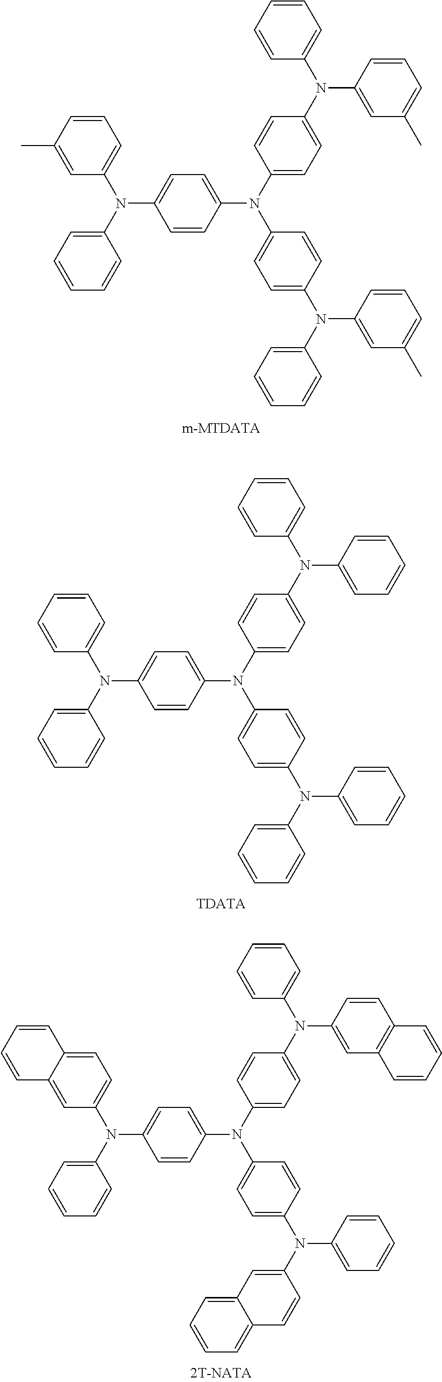

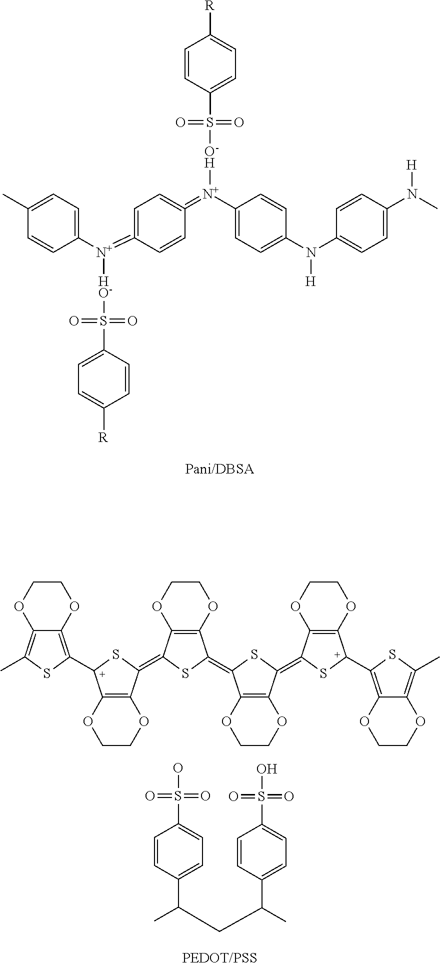

A thickness of the HIL may be about 100 to about 10000 Å, for example, 100 to about 1000 Å. Maintaining the thickness of the HIL at about 100 to about 10000 Å may help ensure that the HIL provides satisfactory hole injecting properties without an increase in driving voltage.

The organic layer 127 may be formed using various methods. For example, the organic layer 127 may be formed using deposition, sputtering, or the like. Alternatively,the organic layer 127 may be formed by using a mixture comprising a material for forming the organic layer (127), which may be a small molecular weight material or a polymer, as described above and solvent e.g., by using.

For example, if the organic layer 127 includes the EML, and the EML is formed on the first layer 125, the EML including a light emitting material, which may be a small molecular weight material or a polymer may be formed by providing a mixture including a light emitting material and a solvent onto the first layer 125, and heating the mixture, i.e., heating the substrate including the mixture thereon. In this regard, the mixture including the light emitting material and the solvent may be provided onto the first layer 125 using, e.g., spin coating, spraying, inkjet printing, dipping, casting, gravure coating, bar coating, roll coating, wire-bar coating, screen coating, flexo coating, or offset coating, but the method is not limited thereto. In this regard, the first layer 125 may include the first material (optionally including an electron injecting material) and/or may be formed using deposition (e.g, thermal deposition) or sputtering. Thus, even when the mixture including the light emitting material and the solvent is provided onto the first layer 125 in order to form the EML, the first layer 125 may not be substantially damaged by the solvent. Thus, an interface between the first layer 125 and the EML may not substantially include an intermixing region in which the material contained in the first layer 125 (i.e., the first material and optionally the electron injecting material) and the light emitting material coexist, and the first layer 125 may have excellent surface characteristics. Thus, a large-sized OLED having excellent electrical characteristics and operational stability may be efficiently prepared. Meanwhile, the organic layer (127) may include the hole injection layer and/or the hole transporting layer. The hole injection layer and/or the hole transporting layer may be formed by providing a mixture including a hole injecting material or a hole transporting material and a solvent onto a region on which a hole injection layer or a hole transport layer is formed, respectively, and heating the substrate including the mixture thereon.

The anode 129 may be formed on the organic layer 127. The anode 129 may be an electrode injecting holes into the organic layer 127.

Examples of a material used to form for the anode 129 may include indium oxide, zinc oxide, tin oxide, a combination thereof, such as indium tin oxide (ITO) or indium zinc oxide (IZO), gold (Au), platinum (Pt), silver (Ag) and copper (Cu), but are not limited thereto. For example, if the anode 129 is formed of ITO, a thickness of the anode 129 may be about 1000 to about 2000 Å. In addition, if the anode 129 is formed of Ag, the thickness of the anode 129 may be about 150 to about 250 Å.

The anode 129 may be formed using various methods, e.g., deposition and sputtering, but is not limited thereto.

FIG. 2 illustrates a schematic sectional view showing a structure of an OLED according to another embodiment. The OLED of FIG. 2 has the same structure as the OLED of FIG. 1, except that an EIL 124 may be disposed between the first layer 125 and the cathode 121. Thus, the structure is described above with reference to FIG. 1.

The EIL 124 may be interposed between the first layer 125 and the cathode 121 so that electrons may be efficiently injected from the cathode 121 to the first layer 125.

The EIL 124 may include an electron injecting material. For example, the EIL 124 may include at least one of LiF, NaCl, CsF, Li₂O and BaF₂, but is not limited thereto. For example, the EIL 124 may include LiF.

The EIL 124 may be formed using various methods, e.g., deposition and sputtering.

A thickness of the EIL 124 may be about 0.1 nm to about 10 nm, for example, about 0.5 nm to about 5 nm. Maintaining the thickness of the EIL 124 at about 0.1 nm to about 10 nm may help ensure that the EIL 124 provides satisfactory electron injecting properties without a substantial increase in driving voltage.

### EXAMPLES

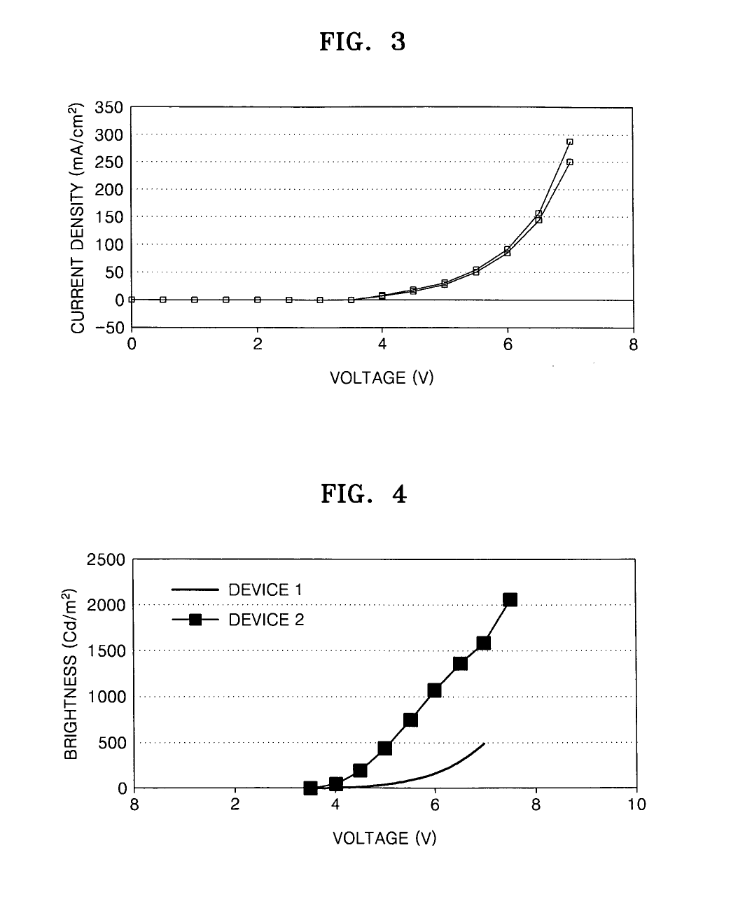

An OLED (hereinafter, referred to as “Device 1”) was prepared by sequentially stacking Al layer (cathode, 700 Å)/LiF layer (EIL, 10 Å)/ZnS layer (first layer, 250 Å)/(ADN+DPVBi) layer (EML, 300 Å, a doping concentration of a dopant of DPVBi was 4 wt %)/NPB layer (HTL, 150 Å)/MTDATA layer (HIL, 700 Å)/ITO layer (anode, 1000 to 2000 Å) on an n-type substrate on which a thin film transistor including a Hf—In—Zn—O-based oxide semiconductor layer was formed. Current density, efficiency, power efficiency, brightness, and color coordinates of Device 1 were measured using a PR650 brightness meter Spectroscan Source Measurement Unit. (PhotoReaserch) and a Keithely 236 (for IVL measurement). In this regard, the first layer was formed using thermal deposition. FIG. 3 illustrates a graph of voltage-current density characteristics of Device 1 measured twice.

Current density, efficiency, power efficiency, brightness and color coordinates of Device 1 according to driving voltage are shown in Table 1 below.

TABLE 1

| Driving | Current | | Power | Bright- | | |
|---|---|---|---|---|---|---|
| voltage | density | Efficiency | Efficiency | ness | X-coor- | Y-coor- |
| (V) | (mA/cm²) | (Cd/A) | (Im/W) | (Cd/m²) | dinate | dinate |
| 4 | 7.90 | 0.080 | 0.063 | 6 | 0.150 | 0.132 |
| 6 | 92.01 | 0.184 | 0.096 | 169 | 0.150 | 0.129 |

Referring to FIG. 3 and Table 1, it may be seen that Device 1 exhibited excellent electrical characteristics.

An OLED (hereinafter, referred to as “Device 2”) was prepared. Device 2 had the same structure as Device 1, except that a first layer (250 Å) including ZnS and LiF that was formed by co-depositing ZnS and LiF was used instead of the first layer (250 Å) including ZnS.

Current density, efficiency, power efficiency, brightness and color coordinates of Device 2 are shown in Table 2 below.

TABLE 2

| Driving | Current | | Power | Bright- | | |
|---|---|---|---|---|---|---|
| voltage | density | Efficiency | Efficiency | ness | X-coor- | Y-coor- |
| (V) | (mA/cm²) | (Cd/A) | (Im/W) | (Cd/m²) | dinate | dinate |
| 5 | 8.11 | 5.577 | 3.503 | 452 | 0.148 | 0.128 |

Referring to Table 2, it is identified that Device 2 has excellent electrical characteristics.

In addition, an OLED (hereinafter, referred to as “Device 3”) was prepared by sequentially stacking Al layer (cathode, 1500 Å)/LiF layer (EIL, 10 Å)/ZnS layer (first layer, 250 Å)/Bebq₂ layer (ETL, 250 Å)/(ADN+DPVBi) layer (EML, 300 Å, a doping concentration of a dopant of DPVBi was 4 wt %)/NPB layer (HTL, 150 Å)/MTDATA layer (HIL, 700 Å)/ITO layer (anode, 1000 to 2000 Å) on an n-type substrate on which a thin film transistor including a Hf—In—Zn—O-based oxide semiconductor layer was formed. An OLED (hereinafter, referred to as “Device 4”) was prepared by sequentially stacking Al layer (cathode, 1500 Å)/LiF layer (EIL, 10 Å)/ZnS layer (first layer, 250 Å)/Bebq₂ layer (ETL, 250 Å)/(ADN+DPVBi) layer (EML, 300 Å, a doping concentration of a dopant of DPVBi was 4 wt %)/NPB layer (first HTL, 50 Å)/NPB layer (second HTL, 200 Å)/PEDOT:PSS layer (HIL, 600 Å)/ITO layer (anode, 1000 to 2000 Å) on an n-type substrate on which a thin film transistor including a Hf—In—Zn—O-based oxide semiconductor layer was formed. Current density, efficiency, power efficiency, brightness, and color coordinates of Devices 3 and 4 were measured using a PR650 brightness meter Spectroscan Source Measurement Unit. (PhotoReaserch) and a Keithely 236 (for IVL measurment). In Device 4, the second HTL was formed by providing a mixture including NPB and an organic solvent onto the first HTL and heat-treating the mixture, and the HIL was formed by providing a PEDOT:PSS solution onto the second HTL and heat-treating the solution.

TABLE 3

| | Driving | Current | | Power | | | |
|---|---|---|---|---|---|---|---|
| | voltage | density | Efficiency | Efficiency | Brightness | | |
| | (V) | (mA/cm²) | (Cd/A) | (Lm/W) | (Cd/m²) | CIEx | CIEy |
| Device 3 | 4.5 | 10.840875 | 6.5935637 | 4.6031758 | 714.8 | 0.1448 | 0.1518 |
| | 5.5 | 66.045 | 6.7105761 | 3.8330721 | 4432 | 0.1438 | 0.1487 |
| Device 4 | 4.5 | 10.40725 | 6.9317063 | 4.8392439 | 721.4 | 0.1442 | 0.1771 |
| | 5.5 | 42.60125 | 6.7744491 | 3.8695563 | 2886 | 0.1437 | 0.1754 |

Referring to Table 3, it may be seen that Devices 3 and 4 exhibited excellent electrical characteristics.

The OLED of an embodiment may exhibit excellent electrical characteristics, may be prepared in a large scale, and may have excellent operational stability.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. An organic light emitting device, comprising:
a substrate;
a thin film transistor on the substrate, the thin film transistor including source and drain electrodes, an oxide semiconductor layer, a gate electrode, and a gate insulating layer that insulates the gate electrode from the source and drain electrodes;
a first insulating layer on the thin film transistor;
a cathode on the first insulating layer, the cathode being connected to one of the source and drain electrodes of the thin film transistor;
a first layer on the cathode, the first layer including a first material, the first material including at least one of metal, metal sulfide, metal oxide, and metal nitride;
an organic layer on the first layer; and
an anode on the organic layer.

2. The organic light emitting device as claimed in claim 1, wherein the oxide semiconductor layer includes a zinc-containing oxide.

3. The organic light emitting device as claimed in claim 1, wherein the oxide semiconductor layer further includes a first component, the first component including at least one of hafnium (Hf), yttrium (Y), tantalum (Ta), zirconium (Zr), gallium (Ga), aluminum (Al), indium (In), iron (Fe), scandium (Sc), lutetium (Lu), ytterbium (Yb), thulium (Tm), erbium (Er), holmium (Ho), manganese (Mn), cobalt (Co), nickel (Ni), titanium (Ti), germanium (Ge), copper (Cu), molybdenum (Mo), and tin (Sn).

4. The organic light emitting device as claimed in claim 1, wherein the cathode includes a material including at least one of magnesium (Mg), aluminum (Al), calcium (Ca), indium (In), and silver (Ag).

5. The organic light emitting device as claimed in claim 1, wherein the first material of the first layer has a work function of about 2.6 eV to about 4.6 eV.

6. The organic light emitting device as claimed in claim 1, wherein the first material of the first layer includes at least one of potassium (K), rubidium (Rb), cesium (Cs), magnesium (Mg), strontium (Sr), barium (Ba), scandium (Sc), yttrium (Y), titanium (Ti), manganese (Mn), zinc (Zn), ytterbium (Yb), potassium sulfide, rubidium sulfide, cesium sulfide, magnesium sulfide, strontium sulfide, barium sulfide, scandium sulfide, yttrium sulfide, titanium sulfide, manganese sulfide, zinc sulfide, ytterbium sulfide, potassium oxide, rubidium oxide, cesium oxide, magnesium oxide, strontium oxide, barium oxide, scandium oxide, yttrium oxide, titanium oxide, manganese oxide, zinc oxide, ytterbium oxide, potassium nitride, rubidium nitride, cesium nitride, magnesium nitride, strontium nitride, barium nitride, scandium nitride, yttrium nitride, titanium nitride, manganese nitride, zinc nitride, and ytterbium nitride.

7. The organic light emitting device as claimed in claim 1, wherein the first layer further includes an electron injecting material.

8. The organic light emitting device as claimed in claim 1, wherein the first layer has a thickness of about 3 nm to about 30 nm.

9. The organic light emitting device as claimed in claim 1, further comprising an electron injection layer interposed between the first layer and the cathode.

10. A method of manufacturing an organic light emitting device, the method comprising:
providing a substrate;
forming a thin film transistor on the substrate such that the thin film transistor includes source and drain electrodes, an oxide semiconductor layer, a gate electrode, and a gate insulating layer that insulates the gate electrode from the source and drain electrodes;
forming a first insulating layer on the thin film transistor;
forming a cathode on the first insulating layer such that the cathode is connected to one of the source and drain electrodes of the thin film transistor;
forming a first layer on the cathode by deposition or sputtering such that the first layer includes a first material including at least one of metal, metal sulfide, metal oxide, and metal nitride;
forming an organic layer on the first layer; and
forming an anode on the organic layer.

11. The method as claimed in claim 10, wherein the oxide semiconductor layer further includes a first component, wherein the first component includes at least one of hafnium (Hf), yttrium (Y), tantalum (Ta), zirconium (Zr), gallium (Ga), aluminum (Al), indium (In), iron (Fe), scandium (Sc), lutetium (Lu), ytterbium (Yb), thulium (Tm), erbium (Er), holmium (Ho), manganese (Mn), cobalt (Co), nickel (Ni), titanium (Ti), germanium (Ge), copper (Cu), and molybdenum (Mo).

12. The method as claimed in claim 10, wherein the first material of the first layer has a work function of about 2.6 eV to about 4.6 eV.

13. The method as claimed in claim 10, wherein the first material of the first layer includes at least one of potassium (K), rubidium (Rb), cesium (Cs), magnesium (Mg), strontium (Sr), barium (Ba), scandium (Sc), yttrium (Y), titanium (Ti), manganese (Mn), zinc (Zn), ytterbium (Yb), potassium sulfide, rubidium sulfide, cesium sulfide, magnesium sulfide, strontium sulfide, barium sulfide, scandium sulfide, yttrium sulfide, titanium sulfide, manganese sulfide, zinc sulfide, ytterbium sulfide, potassium oxide, rubidium oxide, cesium oxide, magnesium oxide, strontium oxide, barium oxide, scandium oxide, yttrium oxide, titanium oxide, manganese oxide, zinc oxide, ytterbium oxide, potassium nitride, rubidium nitride, cesium nitride, magnesium nitride, strontium nitride, barium nitride, scandium nitride, yttrium nitride, titanium nitride, manganese nitride, zinc nitride, and ytterbium nitride.

14. The method as claimed in claim 10, wherein forming the first layer includes depositing or sputtering a first material-forming material and an electron injecting material.

15. The method as claimed in claim 10, further comprising forming an electron injection layer on the cathode prior to forming the first layer.

16. The method as claimed in claim 10, wherein forming the organic layer includes spin coating, spraying, inkjet printing, dipping, casting, gravure coating, bar coating, roll coating, wire-bar coating, screen coating, flexo coating, or offset coating.

17. The method as claimed in claim 10, wherein forming the organic layer includes:
providing a mixture including a light emitting material and a solvent onto a region on which an emission layer is formed, and
heating the substrate including the mixture thereon.

18. The method as claimed in claim 10, wherein forming the organic layer includes:
providing a mixture including a hole injection material and a solvent onto a region on which a hole injecting layer is formed, and
heating the substrate including the mixture thereon.

19. The method as claimed in claim 10, wherein forming the organic layer includes:
providing a mixture including a hole transport material and a solvent onto a region on which a hole transporting layer is formed, and
heating the substrate including the mixture thereon.
